(19) United States
(12) Patent Application Publication
(10) Pub. No.: US 2010/0014270 A1
(43) Pub. Date: Jan. 21, 2010

(54) ELECTROMAGNETIC SHIELDING DEVICE

(76) Inventor: Wei De Liu, Shangahi (CN)

Correspondence Address: 3M INNOVATIVE PROPERTIES COMPANY, PO BOX 33427, ST. PAUL, MN, 55133-3427, US

(21) Appl. No.: 12/523,139

(22) PCT Filed: Jan. 9, 2008
(86) PCT No.: PCT/US2008/050549

§ 371 Date: Jul. 14, 2009

(30) Foreign Application Priority Data
Jan. 25, 2007 (CN) 200710007211.8

(51) Int. Cl. H05K 9/00

(52) U.S. Cl. 361/818

(57) ABSTRACT

A shielding article including a substantially conductive layer; and a substantially magnetically permeable layer adjacent the conductive layer. Embodiments of the invention can feature the substantially conductive layer and the substantially magnetically permeable layer as collectively providing electromagnetic shielding characteristics.

### BACKGROUND

Radio frequency identification devices (RFID) carry data or information that can be accessed by a corresponding receiver. RFID creates an automatic way to collect information about a product, place, time or transaction quickly, easily and without human error. It provides a contactless data link, without need for line of sight or concerns about harsh or dirty environments that restrict other auto ID technologies such as bar codes. In addition, RFID is more than just an ID code, it can be used as a data carrier, with information being written to and updated as necessary or appropriate. The data or information carried and stored within RFID may be susceptible to dissemination and capture by persons not otherwise authorized to receive the data or information. Such unauthorized capture or receipt of RFID data or information presents a problem for those wishing to carry and store data or information safely within RFID.

### SUMMARY

Provided is a shielding article including a substantially conductive layer; and a substantially magnetically permeable layer adjacent the conductive layer. Embodiments of the invention can feature the substantially conductive layer and the substantially magnetically permeable layer as collectively providing electromagnetic shielding characteristics to prevent unauthorized or undesired capture or receipt of data. Embodiments of the invention provide effective shielding when provided on one side of an RFID or when surrounding the RFID.

Also provided is a method of the shielding article. The method includes disposing an apparatus including a radio frequency information component adjacent the conductive layer of the article. The method also includes shielding electromagnetic communication between the radio frequency information component and an external device. The method also includes preventing unauthorized release of information from the radio frequency information component.

### BRIEF DESCRIPTION OF DRAWINGS

FIGS. 1 and 2 illustrate two embodiments of a shielding article and external device according to an embodiment of the invention.

FIGS. 3 and 4 illustrate two embodiments of a shielding article and a cover and external device according to another embodiment of the invention.

FIG. 5 is a graph illustrating a shielding effectiveness curve corresponding to an embodiment of the invention.

FIG. 6 is a graph illustrating a magnetic permeability curve corresponding to an embodiment of the invention.

### DETAILED DESCRIPTION

The present invention includes a multi-layer shielding article 15 that is useful for shielding radio frequency identification devices by interfering with or cutting off the electrical or magnetic radio frequency detecting signal emitted from electromagnetic equipment, electronics equipment, receiving devices, or other external devices.

Embodiments of the multi-layer shielding article 15 can include a substantially conductive layer 25, and a substantially magnetically permeable layer 35 adjacent the substantially conductive layer 25 that operate to shield or otherwise protect a radio frequency information component 40. The substantially conductive layer 25 can include, for example, a high conductivity layer. Such a layer may be made from a metal such as a copper material, for example. Examples of the copper material can include a thickness of about 0.08 mm. In one exemplary embodiment, the copper or other conductive material can have a surface resistance of up to about 0.1 ohm/in². In one exemplary embodiment, the copper or other conductive material can have a surface resistance of up to about 0.05 ohm/in². In another exemplary embodiment, the copper or other conductive material can have a surface resistance up to about 0.005 ohm/in². The surface resistance when reported herein, including the claims, can be measured by placing a sample of conductive material between two gold plated electrodes, each electrode being 1 inch by 1 inch square, with a 2 kg force applied to compress the sample between the electrodes. A DC constant current of 100 mA is applied, and the voltage between the electrodes is measured. Surface resistance

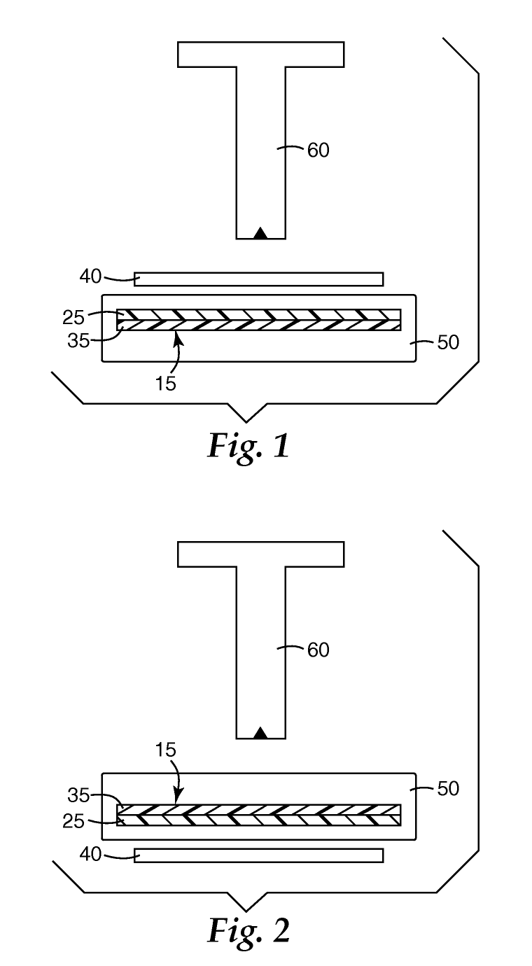

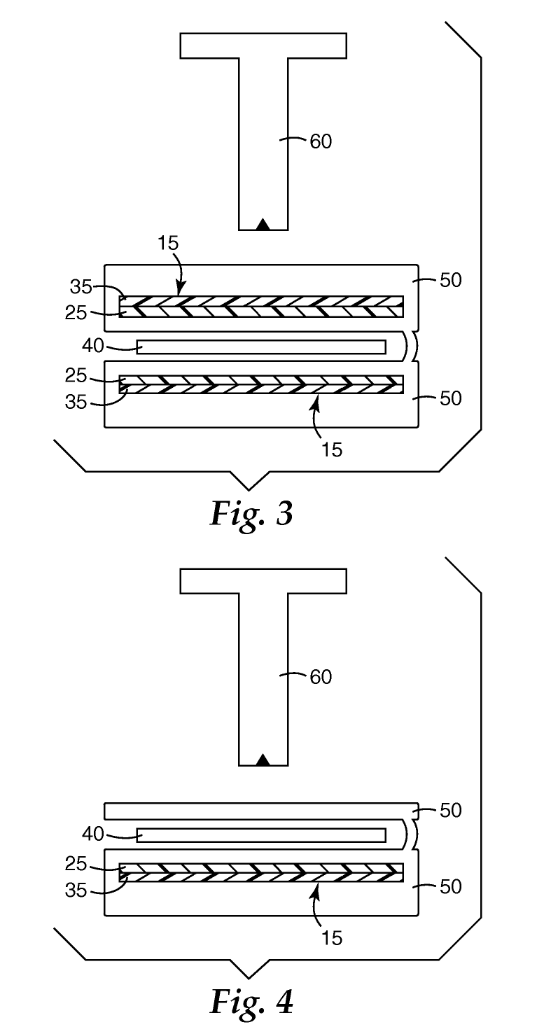

The conductive layer 25 and the magnetically permeable layer 35 are adjacent each other. Optionally, there can be an adhesive between the conductive layer 25 and the magnetically permeable layer 35. Examples can include having a conductive or nonconductive adhesive of a thickness about 0.03 mm interposed between the conductive layer 25 and the magnetically permeable layer 35. Also, for example, embodiments of the conductive layer 25 and the magnetically permeable layer 35 can optionally be collectively wrapped with a layer of conductive fabric. In one embodiment, the conductive layer 25 is closer to the RRID 40. In Another embodiment, the magnetically permeable layer 35 is closer to the RFID 40. In the embodiment illustrated in FIG. 1, the RFID 40 is between the external device 60 and the shielding article 15. This leaves one side of the component 40 substantially free of the conductive and the magnetically permeable layers in the direction of the external device 60. In the embodiment shown in FIG. 2, the shielding article is between the RFID 40 and the external device 60. This leaves one side of the component 40 substantially free of the conductive and magnetically permeable layers in the direction away from the external device 60. In the embodiment of FIG. 3, the shielding article 15 substantially surrounds the RFID 40. In an alternative to the embodiment of FIG. 3, shown in FIG. 4, the portion of the cover 50 that is between the RFID 40 and the external device 60 is substantially free of the conductive layer and the magnetically permeable layer. In this embodiment, the portion of cover 50 that is substantially free of the shielding article 15 may optionally be see through to allow visual inspection of the component 40. Embodiments of the conductive layer 25 and the magnetically permeable layer 35 of the shielding article 15 can collectively provide electromagnetic shielding characteristics sufficient to prevent unauthorized or undesired capture or receipt of data. Embodiments of the invention provide effective shielding when provided on one side of an RRID or when surrounding the RFID. When the shielding article 15 is provided on only one side of the RRID it can be effective between an external device 60 and the component 40, and it can be effective when the component 40 is between the external device 60 and the shielding article 15. When the shielding article is on the opposite side of component 40 from the external device 60, it provides electromagnetic shielding as follows. The external device 60 attempts to capture information from the component 40 by reflecting a radio signal to and from the component 40 In addition, the shielding device 15, even when behind the device 40, also reflects the radio signal back to the device 60. It is this additional reflected signal that interferes with the ability of the external device 60 to be able to get a useful reflected signal from the device 40. One useful method for measuring the effectiveness of the shielding article is provided in China Military Standard SJ20524-1995 (ASTM D4935-99). The substantially conductive layer 25 and the substantially magnetically permeable layer 35 of the multi-layer shielding article 15 collectively prevent magnetic and/or electromagnetic signal penetration from an external device 60 to the radio frequency information component 40.

In operation, an apparatus including a radio frequency information component 40 is disposed or placed adjacent the conductive layer 25 of the multi-layer shielding article 15. The component 40 may optionally be placed adjacent the magnetically permeable layer 35. Examples of the apparatus 40 can include an identification card, an information card, an insurance card, a staff timecard, a smart-card, or any other type apparatus that might carry or store data or information. The radio frequency information component 40 should be placed reasonably close to the conductive layer 25 of the multi-layer shielding article 15. For example, the distance between the conductive layer 25 of the shielding article 15 and the radio frequency information component 40 can be approximately 0.2

In one embodiment, the shielding article 15 can cover both or all sides of the radio frequency information component 40. FIG. 3 shows an embodiment where the multi-layer shielding article 15 covers both sides of the apparatus containing the radio frequency information component 40. A cover 50 for protection of the article 15 can surround the shielding article 15 during its use or operation. The cover 50, for example, can be in the form of a wallet, handbag, folder, or other carrying device as understood by those skilled in the art. In the embodiment shown in FIG. 4, the cover 50 may be substantially free of the magnetically permeable layer and the conductive layer. In this embodiment, the cover 50 may optionally be clear to allow visual inspection of one side of the radio frequency identification component 40. Alternatively, as shown in FIGS. 1 and 2, in some cases the shielding article 15 can effectively shield the radio frequency information component 40 while only covering one side of the radio frequency information component 40.

When the shielding article 15 is properly utilized, the multi-layer shielding article 15 can effectively shield electromagnetic communications between the radio frequency information component 40 and an external device 60, thereby preventing unauthorized release of information from the radio frequency information component 40. On the other hand, when an authorized user desires to gain access to data or information within the radio frequency information component 40, the radio frequency information component 40 can be removed from the multi-layer shielding article 15 structure (e.g., wallet), thereby allowing data or information to be released from the radio frequency information component 40 to the authorized user.

In an exemplary embodiment, the shielding article 15 was tested via a test method applied to the measurement of shielding effectiveness and magnetic permeability of planar materials under normal incidence, far-field, plane-wave conditions.

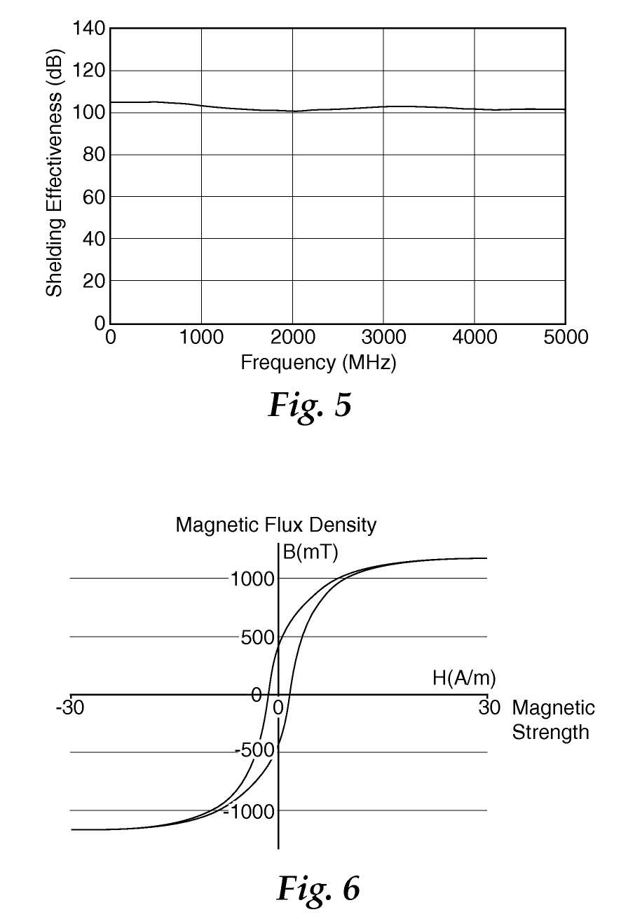

During application, the article 15 can shield the radio frequency information component 40 to produce a shielding effectiveness of greater than 80 dB 110 MHz, as shown in FIG. 5. Also, for example, the article 15 can shield the radio frequency information component 40 to produce a shielding effectiveness of greater than 80 dB @ 5 GHz. Also, for example, the article 15 can shield the radio frequency information component 40 to produce a shielding effectiveness greater than 80 dB anywhere within the frequency range of 10 MHz to 5 GHz. In fact, FIG. 5 shows that the shielding effectiveness can exceed 100 dB through a wide range of frequency. The shielding effectiveness is defined as the ratio of received power with use of the article 15 to received power without use of the article 15.

Additionally, during application, the article 15 can also shield the radio frequency information component 40 to produce a desirable magnetic permeability and relative magnetic permeability, as understood by those skilled in the art. The article 15 can shield the radio frequency information component 40 to produce a relative magnetic permeability greater than 30,000 at 50 Hz, greater than 60,000 at 50 Hz, or greater than 100,000 @ 50 Hz (relative permeability μr is a unitless value resulting from magnetic permeability (μ) divided by vacuum permeability (μ0), as understood by those skilled in the art). FIG. 6 shows the curve for one example or embodiment of the magnetic features of the shielding article 15. The Y-axis represents magnetic flux density with units of mT, and the X-axis represents magnetic strength with units of A/m.

The shielding article 15 can advantageously produce various shielding conditions as measured by China Military Standard SJ20524-1995 (ASTM D4935-99). The substantially conductive layer 25 and the substantially magnetically permeable layer 35 of the multi-layer shielding article 15 collectively prevent magnetic and/or electromagnetic signal penetration from an external device 60 to the radio frequency information component 40.

One particularly useful advantage of the multi-layer shielding article 15 is its ability to prevent theft or otherwise unauthorized acquisition of data or information. The multi-layer shielding article 15 can advantageously prevent data or information from being stolen or otherwise detected by unauthorized users. For example, when an unauthorized user utilizes external electromagnetic or electronics equipment to acquire data or information from a radio frequency information component 40, the multi-layer shielding article 15 can frustrate, impede, and obstruct an attempt to acquire or capture such data or information from the radio frequency information component 40 by substantially cutting off any magnetic and/or electromagnetic detecting signals emitted from the equipment, and/or by reflecting back the detecting signals emitted from the external equipment 60.

Although the aforementioned detailed description contains many specific details for purposes of illustration, anyone of ordinary skill in the art will appreciate that many variations, changes, substitutions, and alterations to the details are within the scope of the invention as claimed. Accordingly, the invention described in the detailed description is set forth without imposing any limitations on the claimed invention. For example, any reference to terms such as mounted, connected, attached, disposed, joined, coupled, interposed, etc. should be construed broadly so as to include such mounting, connecting, attaching, disposing, joining, coupling, interposing, etc. as having been achieved indirectly, directly, and/or integrally. The proper scope of the invention should be determined by the following claims and their appropriate legal equivalents.

1. An article of manufacture comprising:
a substantially conductive layer; and
a substantially magnetically permeable layer disposed adjacent the conductive layer,
wherein the conductive layer and the magnetically permeable layer collectively provide electromagnetic shielding characteristics so as to prevent receipt of data from a radio frequency information component by an external device when the component is located between the external device on one side and the conductive and magnetically permeable layers on the other side.

2. The article as defined by claim 1, wherein the substantially conductive layer comprises a metal and/or the substantially magnetically permeable layer comprises a material including a FeCuNbSiB alloy.

3. The article as defined by claim 2, wherein the substantially conductive layer comprises a surface resistance of up to 0.1 ohm/square inch.

4. The article as defined by claim 1, wherein the substantially magnetically permeable layer comprises a relative permeability of at least 30,000 at 50 Hz.

5. The article as defined by claim 1, further comprising an adhesive between the conductive layer and the magnetically permeable layer.

6. The article as defined by claim 1, wherein the conductive layer and the magnetically permeable layer are collectively wrapped with a layer of conductive fabric.

7. The article as defined by claim 1 in combination with a radio frequency information component, wherein the radio frequency component has a first side and a second side, and wherein the first side is significantly unobstructed by the conductive layer and the magnetically permeable layer.

8. The combination of claim 7, further comprising a visually clear cover positioned on the first side of the radio frequency component.

9. The combination of claim 7, wherein the article provides a shielding effectiveness of greater than 80 dB @ 10 MHz, wherein the shielding effectiveness is defined as the ratio of received power with use of the article to received power without use of the article.

10. A method comprising:
providing an article comprising:
a substantially conductive layer; and
a substantially magnetically permeable layer disposed adjacent the conductive layer,
disposing an apparatus including a radio frequency information component adjacent the conductive layer of the article;
maintaining one side of the radio frequency information component substantially free of the conductive layer and magnetically permeable layer;
shielding electromagnetic communication between the radio frequency information component and an external device; and
preventing unauthorized release of information from the radio frequency information component.
